(19) United States
(12) Patent Application Publication
(10) Pub. No.: US 2007/0152290 A1
(43) Pub. Date: Jul. 5, 2007

(54) Thin film light-activated power switches, photovoltaic devices and methods for making micro-fluid ejected electronic devices

(75) Inventor: Robert Lee Cornell, Lexington, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(73) Assignee: Lexmark International, Inc

(21) Appl. No.: 11/322,418

(22) Filed: Dec. 30, 2005

(51) Int. Cl. H01L 31/06

(52) U.S. Cl. 257/461; 136/263

(57) ABSTRACT

Thin film light-activated power switches, photovoltaic devices and methods for making a micro-fluid ejected electronic device. One such thin film light-activated power switch includes a micro-fluid ejected photoactive device having a first electrode, a second electrode, and a P-N junction between the first electrode and second electrode provided by an n-type organic material and a p-type organic material. The first electrode of the photoactive device is electrically connected to a gate of a micro-fluid ejected transistor device. A power source is connected to the source of the transistor. An electronic device is connected to the drain of the transistor and to the second electrode of the photoactive device. Activation of the photoactive device provides a low voltage signal to the gate of the transistor to provide power from the power source to the electronic device.

### FIELD OF THE DISCLOSURE

The disclosure is directed to micro-fluid ejected electronic devices and in particular to micro-fluid ejected photovoltaic switching devices and methods for making the devices.

### BACKGROUND AND SUMMARY

Semiconductor electronic devices such as transistors, capacitors, resistors, solar cells, and the like are typically made using elaborate equipment by processes including, but not limited to, photolithography, vacuum deposition, chemical vapor deposition, oxidation, etching, masking, dopant diffusion, and the like. Many of the foregoing process steps are relatively slow and difficult to control. Furthermore, the equipment required to make such devices on a large scale is expensive and often requires clean room environments.

As the uses of semiconductor and electronic devices continue to grow and diversify, there is a continuing need for faster, more economical production processes for electronic devices.

With regard to the foregoing needs, exemplary embodiments of the disclosure provide a thin film light-activated power switch, a photovoltaic device and a method for making a micro-fluid ejected electronic device. One such thin film light-activated power switch includes a micro-fluid ejected photoactive device having a first electrode, a second electrode, and a P-N junction between the first electrode and second electrode provided by an n-type organic material and a p-type organic material. The first electrode of the photoactive device is electrically connected to a gate of a micro-fluid ejected transistor device. A power source is connected to the source of the transistor. An electronic device is connected to the drain of the transistor and to the second electrode of the photoactive device. Activation of the photoactive device provides a low voltage signal to the gate of the transistor to provide power from the power source to the electronic device.

Another exemplary embodiment of the disclosure provides a method for making a micro-fluid ejected electronic device. The method includes depositing a source conductor and a drain conductor on a substrate by a micro-fluid ejection process. A polymeric semiconductor material is deposited on at least a portion of the source conductor and at least a portion of the drain conductor by a micro-fluid ejection process. An electrically insulating material is deposited over the semiconductor material and the source conductor and drain conductor by a micro-fluid ejection process. A gate conductor is deposited on at least a portion of the insulating material by a micro-fluid ejection process. A first electrode is deposited in electrical communication with the gate conductor over the gate conductor and insulating material by a micro-fluid ejection process. An n-type organic material is deposited on the first electrode by a micro-fluid ejection process. A p-type organic material is deposited on the n-type organic material by a micro-fluid ejection process. An at least translucent second electrode is deposited on the p-type organic material by a micro-fluid ejection process.

A further exemplary embodiment of the disclosure provides a photovoltaic device made by a micro-fluid ejection process. The device includes a substrate, a micro-fluid ejected conductor deposited on the substrate, a micro-fluid ejected n-type organic material deposited on the conductor, a micro-fluid ejected p-type organic material deposited on the n-type organic material to provide a P-N junction, and a micro-fluid ejected at least translucent electrode deposited on the p-type organic material.

An advantage of at least some of the foregoing embodiments is that an electronic switching device may be provided using relatively inexpensive equipment. Such a switching device has an advantage with regard to types of substrates that may be used and ease of layout changes for electronic components of the switching device.

### BRIEF DESCRIPTION OF THE DRAWINGS

Further advantages of the exemplary embodiments may become apparent by reference to the detailed description when considered in conjunction with the elements through the several views, and wherein:

FIGS. 1 and 2 are schematic illustrations of a switching device according to the disclosure;

FIG. 3 is a perspective view, not to scale, of a greeting card containing a switching device according to the disclosure;

FIG. 4 is a schematic illustration of a process for depositing conductive, semiconductive, and insulating material on a substrate according to the disclosure; and

FIG. 5 is a schematic illustration of a switching device according to another exemplary embodiment of the disclosure.

### DETAILED DESCRIPTION OF EXEMPLARY EMBODIMENTS

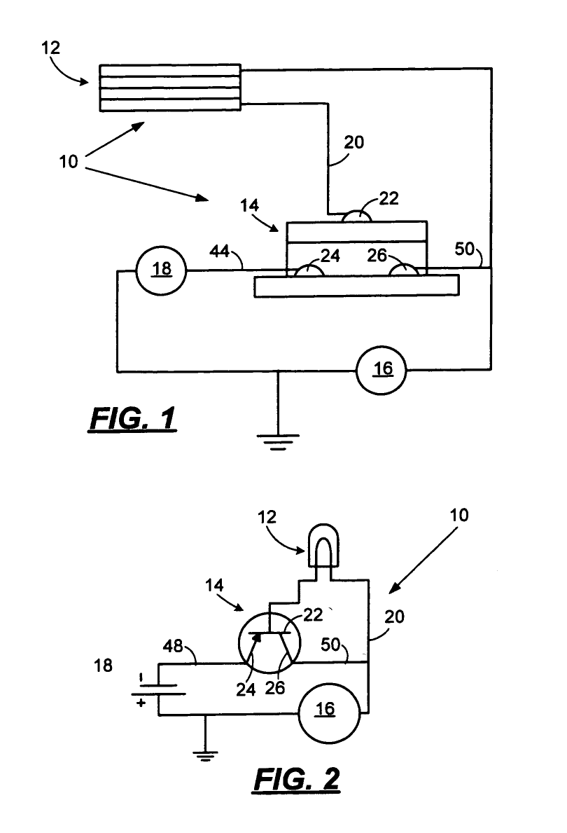

With reference to FIGS. 1 and 2, there are shown schematic drawings of a switching device 10 according to an exemplary embodiment of the disclosure. The switching device 10 includes a photovoltaic component 12 and a transistor component 14. The switching device 10 may be used to activate a load 16 such as an electronic display, motor, or the like that is connected to a power source 18. When light is present, the photovoltaic component 12 is activated and sends an electrical signal via conductor 20 to power a gate 22 of the transistor component 14. When light is no longer present, the photovoltaic component 12 is no longer activated hence no electrical signal is sent to the gate 22 of the transistor component 14. Since the gate 22 is not activated, there will be no current flowing from a source region 24 to a drain region 26 providing an open circuit configuration with respect to the load 16.

While not desiring to be bound by theory, in the presence of light, it is believed that the photovoltaic component 12 generates a negative electrical charge that is applied to the gate 22 of the transistor component 14. The negative electrical charge on the gate 22 of the transistor component 14 repels electrons downward providing a relatively electron rich region in the transistor component 14, which allows current to flow from the source region 24 to the drain region 26. Since the photovoltaic component 12 generates a low voltage, there is not enough energy generated by the photovoltaic component 12 to power the load 16 directly. Accordingly, the switching device 10 includes the power source 18 that is the main source of power for the load 16.

An advantage of the switching device 10 described above, could be that the device 10 may be used to activate devices such as electroluminescence displays that need high voltage to operate. The foregoing device 10 allows high voltage to flow to the load 16 only when light is present, thus not draining batteries or other power sources 18 when the load 16 is not needed.

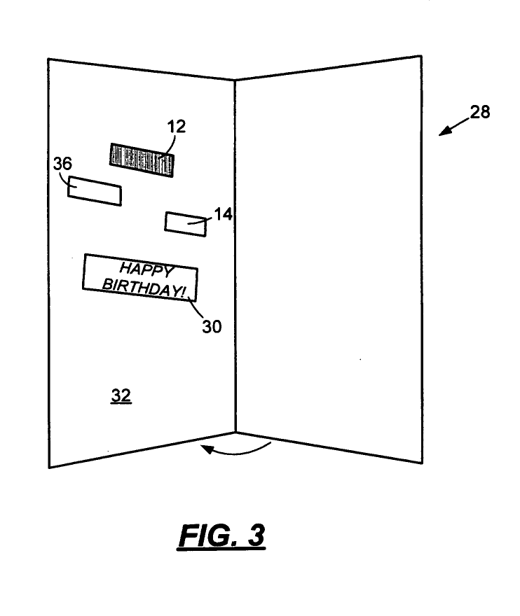

An example of a load 16 powered by the switching device 10 described above is illustrated in FIG. 3. The switching device 10 is deposited onto a card stock providing a greeting card 28 by a micro-fluid ejection process. In this case, the load 16 is an electroluminescent display or liquid crystal display 30 on an inside flap 32 of the greeting card 28. The display 30 is powered by a battery or batteries 36. When the card 28 is opened, light activates the photovoltaic component 12 sending an electrical signal to the gate 22 of the transistor component 14 thereby completing the circuit from the batteries 36 to the display 30. When the card 28 is closed, the circuit is opened and the power to the display 30 is terminated. The foregoing switching device 10 may also be adapted to complete the circuit from the batteries in the absence of light and to open the circuit in the presence of light.

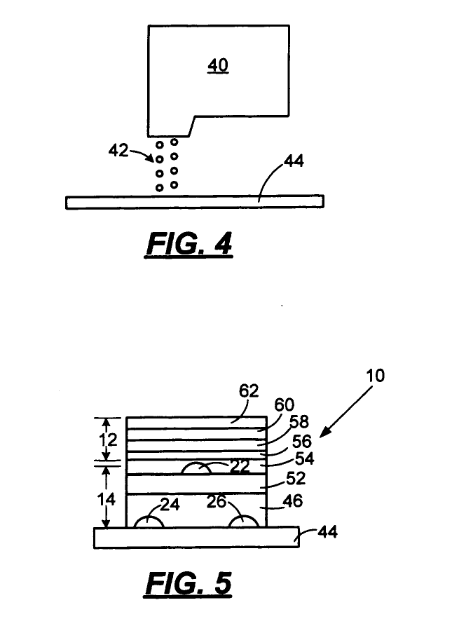

A process for making the switching device 10 will now be described. Each of the photovoltaic component 12 and transistor component 14 may be deposited on a single substrate in spaced-apart locations, on separate substrates, or as shown in FIG. 4, the photovoltaic component 12 and transistor component 14 may be combined in a single location on a substrate 40. Both the photovoltaic component 12 and the transistor component 14 are made of organic semiconductor materials that may be ejected onto the substrate by a micro-fluid ejection device.

A micro-fluid ejection head 40 may be used to eject conductive, semiconductive, and insulative fluids 42 onto a substrate 44 as shown in FIG. 4. In a first step of the process, two conductive, non-contacting traces are deposited using a conductive ink onto the substrate 44 to provide the source region 24 and drain region 26 of the transistor (FIG. 5). The substrate 44 may be a flexible or rigid substrate 44 made of a non-conducting material such as paper, plastic film, fiberglass, ceramic, glass, natural or synthetic rubber, and the like. For a flexible switching device 10, the substrate 44 may be a coated or uncoated paper substrate. The conductive ink providing the source region 24 and drain region 26 may include silver particles, copper particles, carbon particles, and the like, and may be deposited by the micro-fluid ejection process described above. The thickness of the source region 24 and drain region 26 may range from about 20 nm to about 10 microns.

Next, a polymeric semiconductor layer 46 is deposited by a micro-fluid ejection process onto the substrate 44 so that it covers the source region 24 and the drain region 26. It will be appreciated that conductive leads 48 and 50 (FIG. 1), not covered by the polymeric semiconductor layer 46, may be provided for providing electrical contact to the source region 24 and drain region 26. The polymeric semiconductor layer 46 may include an n-type or p-type polythiophene material as the polymeric semiconductor layer 46, and may be deposited with a thickness ranging from about 20 nm to about 10 microns.

A first insulating layer 52 is then deposited by a micro-fluid ejection process on the polymeric semiconductor layer 46. The first insulating layer 52 has a thickness ranging from about 20 nm to about 10 microns and may be made from an epoxy or acrylic dielectric material or may be a hydrated silicon dioxide that is ejected from a micro-fluid ejection device as an opal fluid.

A conductive trace providing the gate 22 and containing a conductive lead is then deposited onto a portion of the insulating layer 52. As with the source region 24 and drain region 26, the conductive trace providing the gate 22 may be deposited with a conductive ink, as described above using a micro-fluid ejection process. The gate has a thickness ranging from about 20 nm to about 10 microns.

In order to provide the photovoltaic component 12, a second insulating layer or substrate 54 is deposited using a micro-fluid ejection process over the gate 22 and first insulating layer 52. The second insulating layer 54 may be made of the same material as the first insulating layer 52 and may be deposited using a similar micro-fluid ejection process.

A conductive layer 56 is deposited on the gate 22 and second insulating layer 54 using a micro-fluid ejection process. The conductive layer 56 may also be made of a conductive ink as described above. The thickness of the conductive layer 56 may range from about 20 nm to about 10 microns. The conductive layer 56 may also provide the conductor 20 for electrical contact with a conductive trace providing the gate 22.

The photovoltaic component 12 includes an n-type semiconductor layer 58 in contact with a p-type semiconductor layer 60. The n-type semiconductor layer 58 may be provided by the polythiophene material described above having perfluoroarene groups attached thereto. The thickness of the n-type semiconductor layer 58 may range from about 20 nm to about 10 microns. A micro-fluid ejection process may be used to deposit the n-type semiconductor layer 58.

The p-type semiconductor layer 60 is then deposited on at least a portion of the n-type semiconductor layer 58 to provide a P-N junction for the photovoltaic component 12. The p-type semiconductor layer 60 includes pentacene which is inherently a p-type semiconductor material. As with the n-type semiconductor layer 58, the p-type semiconductor layer 60 may be deposited using a micro-fluid ejection process.

Finally, a top electrode layer 62 is deposited onto the p-type semiconductor layer 60 by a micro-fluid ejection process. Top electrode layer 60 is deposited with a thickness that enables light to penetrate the electrode layer and activate the P-N junction of the photovoltaic component 12. For example, a silver ink may be deposited by a micro-fluid ejection process with a thickness ranging from about 20 nm to about 10 microns to provide a substantially transparent (“translucent”) top electrode layer 62. In the alternative, at least translucent conductive materials selected from indium tin oxide, zinc oxide, aluminum- or boron-doped zinc oxide, cadmium sulfide, cadmium oxide, tin oxide and fluorine-doped tin oxide may be used as the top electrode layer 62.

Organic semiconductor materials and methods for making semiconductor devices using such materials are described for example in U.S. Pat. No. 6,608,323, the disclosure of which is incorporated herein by reference. Drop on demand printing techniques are described for example in U.S. Pat. No. 6,503,831, the disclosure of which is incorporated herein by reference.

Having described various aspects and embodiments herein and several advantages thereof, it will be recognized by those of ordinary skill that the disclosed embodiments are susceptible to various modifications, substitutions and revisions within the spirit and scope of the appended claims.

What is claimed is:

1. A thin film light-activated power switch, comprising:
a micro-fluid ejected photoactive device having a first electrode, a second electrode, and a P-N junction between the first electrode and second electrode provided by an n-type organic material and a p-type organic material;
a micro-fluid ejected transistor device having a gate, a source, and a drain wherein the first electrode of the photoactive devices is electrically connected to the gate of the transistor;
a power source connected to the source of the transistor; and
an electronic device connected to the drain of the transistor and to the second electrode of the photoactive device,
wherein activation of the photoactive device provides a low voltage signal to the gate of the transistor to provide power from the power source to the electronic device.

2. The thin film power switch of claim 1, wherein the photoactive device comprises a photovoltaic device.

3. The thin film power switch of claim 2, wherein the p-type organic material comprises a crystalline organic material.

4. The thin film power switch of claim 1, wherein at least one of the first electrode and second electrode comprises an at least translucent material selected from the group consisting of indium tin oxide, zinc oxide, aluminum-doped zinc oxide, boron-doped zinc oxide, cadmium sulfide, cadmium oxide, tin oxide, and fluorine-doped tin oxide.

5. The thin film power switch of claim 1, wherein the photoactive device is deposited on the transistor.

6. The thin film power switch of claim 1, wherein the n-type organic material comprises a perfluoroarene substituted polythiophene compound.

7. The thin film power switch of claim 1, wherein the p-type organic material comprises a pentacene compound.

8. The thin film power switch of claim 1, wherein the photoactive device has an overall thickness ranging from about 100 nm to about 100 microns.

9. A photovoltaic device, comprising:
a substrate;
a micro-fluid ejected conductor deposited on the substrate;
a micro-fluid ejected n-type organic material deposited on the conductor;
a micro-fluid ejected p-type organic material deposited on the n-type organic material to provide a P-N junction;
a micro-fluid ejected at least translucent electrode deposited on the p-type organic material.

10. The photovoltaic device of claim 9, wherein the p-type organic material comprises a crystalline organic material.

11. The photovoltaic device of claim 9, wherein the at least translucent electrode comprises a material selected from the group consisting of indium tin oxide, zinc oxide, aluminum-doped zinc oxide, boron-doped zinc oxide, cadmium sulfide, cadmium oxide, tin oxide, fluorine-doped tin oxide, and silver.

12. The photovoltaic device of claim 9, wherein the substrate comprises a micro-fluid ejected transistor device deposited on another substrate.

13. The photovoltaic device of claim 9, wherein the n-type organic material comprises a perfluoroarene substituted polythiophene compound.

14. The photovoltaic device of claim 9, wherein the p-type organic material comprises a pentacene compound.

15. A method for making a micro-fluid ejected electronic device, comprising:
depositing a source conductor and a drain conductor on a substrate by a micro-fluid ejection process;
depositing a polymeric semiconductor material on at least a portion of the source conductor and at least a portion of the drain conductor by a micro-fluid ejection process;
depositing an electrically insulating material over the semiconductor material and the source conductor and drain conductor by a micro-fluid ejection process;
depositing a gate conductor on at least a portion of the insulating material by a micro-fluid ejection process;
depositing a first electrode in electrical communication with the gate conductor over the gate conductor and insulating material by a micro-fluid ejection process;
depositing an n-type organic material on the first electrode by a micro-fluid ejection process;
depositing a p-type organic material on the n-type organic material by a micro-fluid ejection process;
depositing an at least translucent second electrode on the p-type organic material by a micro-fluid ejection process.

16. The method of claim 15, wherein the p-type organic material comprises a crystalline organic material.

17. The method of claim 15, wherein the at least translucent second electrode comprises a material selected from the group consisting of indium tin oxide, zinc oxide, aluminum-doped zinc oxide, boron-doped zinc oxide, cadmium sulfide, cadmium oxide, tin oxide, fluorine-doped tin oxide, and silver.

18. The method of claim 15, wherein the n-type organic material comprises a perfluoroarene substituted polythiophene compound.

19. The method of claim 15, wherein the p-type organic material comprises a pentacene compound.

20. The method of claim 15, further comprising connecting a power source to the source conductor and to an electrical load, and connecting the second electrode to the drain conductor and to the electrical load.
